(19) United States
(12) Patent Application Publication
(10) Pub. No.: US 2024/0128710 A1
(43) Pub. Date: Apr. 18, 2024

(54) LIGHT-EMITTING DEVICE

(71) Applicant: NICHIA CORPORATION, Anan-shi (JP)

(72) Inventors: Yoshihiro KIMURA, Yokohama-shi (JP); Tadaaki MIYATA, Yokohama-shi (JP)

(21) Appl. No.: 18/487,043

(22) Filed: Oct. 14, 2023

(30) Foreign Application Priority Data
Oct. 17, 2022 (JP) 2022-166216

(51) Int. Cl. H01S 5/02345; H01S 5/02315; H01S 5/42

(52) U.S. Cl. CPC H01S 5/02345; H01S 5/02315; H01S 5/423; H01S 5/18361

(57) ABSTRACT

A light-emitting device includes a substrate, a base disposed on the substrate, a light-emitting element disposed over the base, a frame body, and at least one of a functional element and a wire. The frame body includes an inner wall surface surrounding the base and the light-emitting element, an upper surface, and a lower surface connected to the substrate. At least one of the functional element and the wire is disposed on the substrate. At least a part of the at least one of the functional element and the wire is disposed below the light-emitting element. The inner wall surface includes an inclined surface that is inclined so that a distance between the inclined surface and the light-emitting element increases from an upper surface side toward a lower surface side. The at least one of the functional element and the wire is disposed between the inclined surface and the base.

### CROSS-REFERENCE TO RELATED APPLICATIONS

This application claims priority to Japanese Patent Application No. 2022-166216, filed on Oct. 17, 2022. The entire disclosure of Japanese Patent Application No. 2022-166216 is hereby incorporated herein by reference.

### BACKGROUND

The present invention relates to a light-emitting device.

JP 2005-183558 A discloses a light-emitting device in which inclined surfaces are provided on side walls of a frame body surrounding a light-emitting diode and a photodiode.

### SUMMARY

A light-emitting device that includes a light-emitting diode, a functional element, such as a photodiode, and a wire, and is more compact is provided.

A light-emitting device disclosed in one embodiment includes a substrate, a base disposed on the substrate, a light-emitting element disposed over the base, a frame body, and at least one of a functional element and a wire. The frame body includes an inner wall surface surrounding the base and the light-emitting element, an upper surface, and a lower surface, the lower surface being connected to the substrate. At least one of the functional element and the wire is disposed on the substrate. At least a part of the at least one of the functional element and the wire is disposed below the light-emitting element. The inner wall surface includes an inclined surface that is inclined so that a distance between the inclined surface and the light-emitting element increases from an upper surface side toward a lower surface side. The at least one of the functional element and the wire is disposed between the inclined surface and the base.

In one embodiment or at least one of a plurality of embodiments disclosed in this description, a more compact light-emitting device can be provided.

### BRIEF DESCRIPTION OF DRAWINGS

FIG. 1A is a perspective view of a light-emitting device according to one embodiment.

FIG. 1B is a perspective view of a light-emitting device according to one embodiment.

FIG. 2 is a perspective view of the light-emitting device according to the one embodiment illustrated in a state in which an inside of the light-emitting device can be seen through a lid body.

FIG. 3 is a cross-sectional view taken along a section line in FIG. 1A.

FIG. 4A is a top view of a substrate according to the one embodiment.

FIG. 4B is a bottom view of the substrate according to the one embodiment.

FIG. 5A is a top view of a submount according to the one embodiment.

FIG. 5B is a bottom view of the submount according to the one embodiment.

FIG. 6A is a schematic plan view for describing a structure of a light-emitting element according to the one embodiment.

FIG. 6B is a cross-sectional view taken along a section line VIB-VIB in FIG. 6A.

FIG. 7 is a top view of a state in which the lid body and a frame body are removed from the light-emitting device according to the one embodiment.

FIG. 8 is a cross-sectional view of a light-emitting device according to a modification example of the one embodiment.

### DETAILED DESCRIPTION

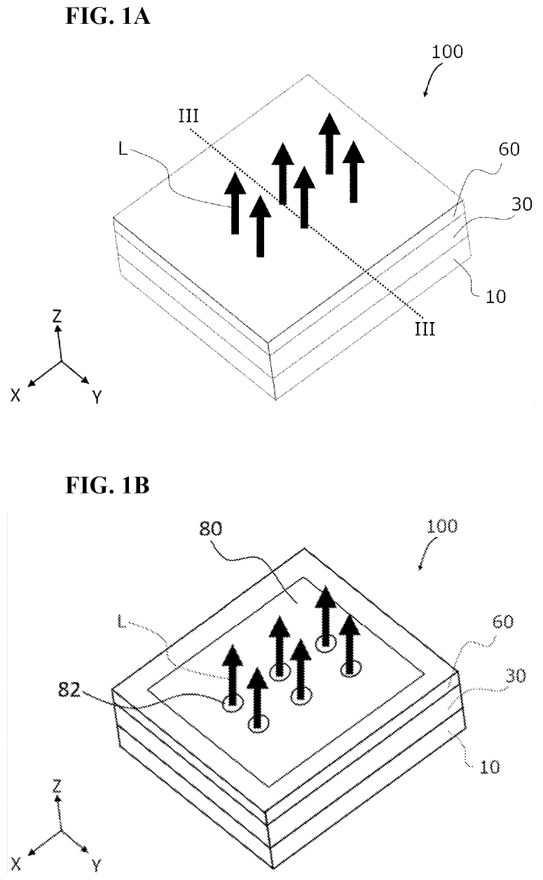

A light-emitting device illustrating one example of an embodiment according to the present invention will be described below with reference to FIGS. 1A to 8. The drawings referred to in the following description are diagrams that schematically illustrate the present embodiment, and thus scales and intervals of members, positional relationships, and the like are exaggerated, or some of the members are not illustrated in the drawings, in some cases. Furthermore, in the following description, members having the same terms and reference characters, in principle, represent the same members or homogeneous members, and a detailed description of such members will be omitted as appropriate.

For clarity of explanation, the arrangements and structures of portions will be described using the XYZ orthogonal coordinate system in the following description. The X, Y, and Z-axes are orthogonal to each other. In the drawings, for directions along the X-axis, the arrow direction is referred to as a “+X direction”, and the opposite direction is referred to as a “−X direction”. In addition, for the directions along the Y-axis, the arrow direction is referred to as a “+Y direction”, and the opposite direction is referred to as a “−Y direction”. In addition, for the directions along the Z-axis, the arrow direction is referred to as a “+Z direction”, and the opposite direction is referred to as a “−Z direction”. The +Z direction is the upward direction and the −Z direction is the downward direction, but these directions have no relation to the direction of gravity.

A view in the +Z direction is referred to as a “top view”, and a view in the −Z direction is referred to as a “bottom view”. In the present specification or the scope of the claims, expressions such as upper and lower, and left and right are used merely to describe a relative relationship of positions, orientations, directions, and the like, and the expressions need not necessarily match a relationship at a time of use.

One example of the light-emitting device according to the present embodiment will be described below.

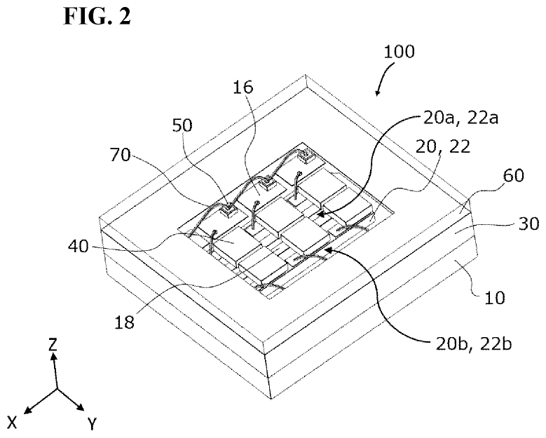

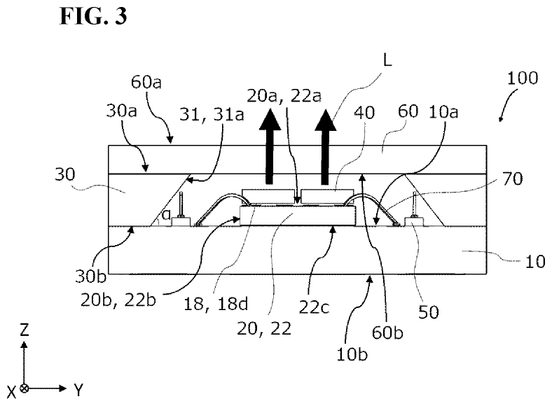

FIGS. 1A and 2 are perspective views of a light-emitting device 100 according to the embodiment, and FIG. 2 is a perspective view of the light-emitting device 100 illustrated in a state in which an inside thereof can be seen through a lid body 60 in the light-emitting device 100 in FIG. 1A. FIG. 3 is a cross-sectional view taken along a section line in FIG. 1A. As illustrated in FIGS. 1A to 3, the light-emitting device 100 includes a substrate 10, a base 20, a frame body 30, light-emitting elements 40, and functional elements 50. The light-emitting device 100 may include components other than these. The light-emitting device 100 need not include some of the components described above.

First, each of the components will be described.

Substrate 10

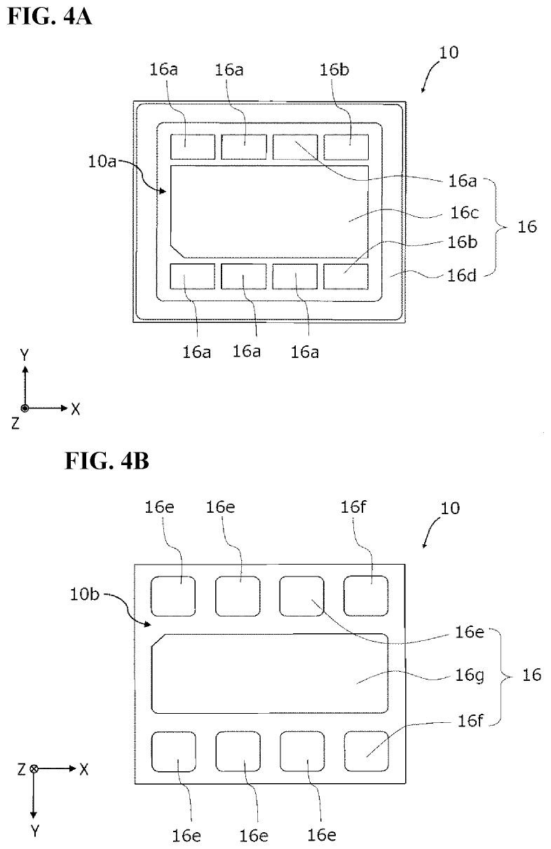

FIG. 4A is a top view of the substrate 10 according to the embodiment, and FIG. 4B is a bottom view of the substrate 10 according to the embodiment. As illustrated in FIGS. 3, 4A, and 4B, the substrate 10 is a plate-shaped member including an upper surface 10a and a lower surface 10b as a surface opposite to the upper surface 10a. The substrate 10 can be formed, for example, using a ceramic or a metal as a main material. Specifically, a ceramic, such as AlN, SiC, or SiN, or a metal containing at least one selected from the group consisting of Cu, Al, Ag, Fe, Ni, Mo, Cu, W, and CuMo can be used as the main material of the substrate. Alternatively, the main material of the substrate 10 may be a resin.

First conductive members 16 are formed on the upper surface 10a and the lower surface 10b of the substrate 10. As illustrated in FIG. 4A, on the upper surface 10a of the substrate 10, anode wiring lines 16a, cathode wiring lines 16b, a heat dissipation wiring line 16c, and a connection wiring line 16d are formed. The connection wiring line 16d is disposed in a quadrangular frame shape at a peripheral edge of the upper surface 10a of the substrate 10, and the anode wiring lines 16a, the cathode wiring lines 16b, and the heat dissipation wiring line 16c are arranged within this frame. The heat dissipation wiring line 16c is disposed in a central portion of the upper surface 10a of the substrate 10. While the anode wiring line 16a, the cathode wiring line 16b, and the heat dissipation wiring line 16c each have a rectangular shape, they may have a circular shape, an elliptical shape, or the like.

Also, on the lower surface 10b of the substrate 10, anode electrodes 16e, cathode electrodes 16f, and a heat dissipation electrode 16g as external connection terminals are formed. The heat dissipation electrode 16g is disposed in a central portion of the lower surface 10b of the substrate 10, and the anode electrodes 16e and the cathode electrodes 16f are disposed around the heat dissipation electrode 16g. While the anode electrode 16e, the cathode electrode 16f, and the heat dissipation electrode 16g each have a rectangular shape, they may have a circular shape, an elliptical shape, or the like.

The anode wiring lines 16a and the anode electrodes 16e, and the cathode wiring lines 16b and the cathode electrodes 16f are electrically connected through vias penetrating the substrate 10 in the Z direction. In addition, it is preferable that the heat dissipation wiring line 16c and the heat dissipation electrode 16g are also thermally connected through vias. Thus, the heat dissipation property can be improved.

The first conductive member 16 may be formed of a metal material, such as tungsten, molybdenum, nickel, gold, silver, platinum, titanium, copper, aluminum, ruthenium, or chromium. The first conductive member 16 may have a multilayer structure in which layers are electrically connected to each other through vias. In a case in which the substrate 10 itself is made of a metal, the surfaces and/or the inside of the substrate 10 are subjected to insulation treatment in order to dispose the first conductive members 16. A thickness in the Z direction of the substrate 10 in the present embodiment is in the range from 0.1 mm to 1 mm, and may be, for example, about 0.5 mm.

Base 20

The base 20 is a protruding portion protruding from the upper surface 10a of the substrate 10. The base 20 may be formed integrally with the substrate 10 described above, or may be a member separate from the substrate 10 as illustrated in FIG. 3. In a case in which the base 20 is formed as a separate member from the substrate 10, the base 20 is referred to as a submount 22.

In a case in which the base 20 is integrally formed with the substrate 10, the same material as that of the substrate 10 can be used as the material of the base 20. Also, even in a case in which the submount 22 is used as the base 20, the same material as that of the substrate 10 can be used for the submount 22.

A second conductive member 18 is formed at least on an upper surface 20a of the base 20. The same material as that of the first conductive member 16 can be used for the second conductive member 18. In addition, in a case in which the base 20 itself is made of a metal, the surfaces and/or an inside of the base 20 are subjected to insulation treatment in order to dispose the second conductive member 18.

The base 20 includes, for example, the upper surface 20a and a lateral surface 20b. In the example of FIG. 3, the lateral surface 20b of the base 20 is parallel to the Z direction, and the base 20 has a rectangular parallelepiped shape. However, the base 20 is not limited to a rectangular parallelepiped shape. A thickness in the Z direction of the base 20 in the present embodiment is in the range from 0.1 mm to 0.5 mm, and may be, for example, about 0.2 mm. The thickness of the base 20 refers to a length in the Z direction from the upper surface 10a of the substrate 10 to the upper surface 20a of the base 20. In a case in which the base 20 is the submount 22, the thickness of the base 20 is a thickness in the Z direction of the submount 22.

Submount 22

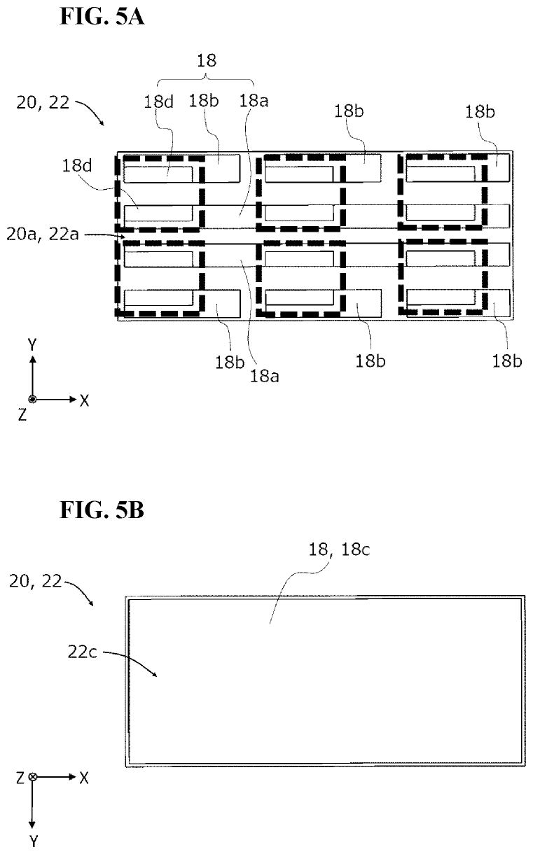

FIGS. 3, 5A, and 5B illustrate one example of the submount 22 that can be used as the base 20. The submount 22 is a rectangular parallelepiped member including an upper surface 22a, a lateral surface 22b, and a lower surface 22c. The upper surface 22a and the lower surface 22c have a rectangular outer shape having a long side along the X direction and a short side along the Y direction, and have a length in the Z direction that is shorter than the long side and the short side. The submount 22 is not limited to a rectangular parallelepiped shape, and areas of the upper surface 22a and the lower surface 22c may be different. In that case, the lateral surface is an inclined surface inclined with respect to the Z direction.

FIGS. 5A and 5B illustrate one example of the second conductive members 18 formed on the upper surface 22a and the lower surface 22c of the submount 22. The second conductive member 18 includes a common wiring line 18a disposed so as to be connected from the vicinity of one short side to the vicinity of the other short side along the long side of the upper surface 22a, that is in the X direction, and individual wiring lines 18b disposed separately in three along the X direction. The common wiring lines 18a are disposed in parallel being arranged in two rows at a central portion in the Y direction of the upper surface 22a. The individual wiring lines 18b are disposed along the long side at the end portions in the +Y direction and the −Y direction of the upper surface 22a. Bonding layers 18d are disposed on upper surfaces of the common wiring line 18a and the individual wiring line 18b. In addition, the second conductive member 18 includes a connection wiring line 18c having a substantially similar shape to that of the lower surface 22c on the lower surface 22c of the submount 22.

Frame Body 30

The frame body 30 is formed of, for example, any one of silicon, glass, and ceramic. A thickness in the Z direction of the frame body 30 in the present embodiment is in the range from 0.2 mm to 2 mm, and may be, for example, about 0.5 mm.

The frame body 30 includes an upper surface 30a, a lower surface 30b, and an inner wall surface 31. The inner wall surface 31 includes an inclined surface 31a inclined outward from the upper surface 30a toward the lower surface 30b.

The inclined surface 31a is an inversely tapered inclined surface formed along a circumferential direction of the inner wall surface 31, and is inclined increasing a distance from an inside of the light-emitting device 100 from the upper surface 30a side toward the lower surface 30b side.

The inclined surface 31a may be continuously present over the entire circumference along the circumferential direction of the inner wall surface 31. Alternatively, the inclined surface 31a may be discontinuous or partially present along the circumferential direction of the inner wall surface 31. A proportion at which the inclined surface 31a is partially present with respect to the entire circumference of the inner wall surface 31 may be, for example, equal to or more than 50% and less than 100%.

The inclined surface 31a can be formed by processing the inner wall surface 31 using, for example, a laser processing device or sandblast processing. In addition, for example, the inclined surface 31a can be formed by performing wet etching in a case in which the material of the frame body 30 is silicon.

Light-Emitting Element 40

Examples of the light-emitting element 40 include a semiconductor laser element. As the semiconductor laser element, a surface-emitting semiconductor laser element or an edge-emitting semiconductor laser element can be used. As the surface-emitting semiconductor laser element, a vertical cavity surface emitting laser (VCSEL) element, a photonic crystal surface emitting laser (PCSEL) element, or the like may be used. Hereinafter, the vertical cavity surface emitting laser element will be referred to as a VCSEL element. The light-emitting element 40 is not limited to the semiconductor laser element, and a light-emitting diode (LED) or the like may be employed.

The light-emitting element 40 is a single emitter including at least one emitter. Note that the light-emitting element 40 may be a multi-emitter including two or more emitters.

Light emitted from the light-emitting element 40 is divergent light that spreads. Note that the light need not be the divergent light. In a case in which the light-emitting element 40 is a semiconductor laser element, the divergent light (laser light) emitted from the semiconductor laser element forms a far field pattern (hereinafter referred to as an “FFP”) of a circular shape on a plane parallel to a light-emitting surface. The FFP indicates a shape and a light intensity distribution of the emitted light at a position separated from the light-emitting surface.

Light passing through the center of the circular shape of the FFP, in other words, light having a peak intensity in the light intensity distribution of the FFP, is referred to as light traveling along an optical axis. The optical path of the light traveling along the optical axis is referred to as the optical axis of the light. Based on the light intensity distribution of the FFP, light having an intensity of 1/e² or more with respect to a peak intensity value may be referred to as a “beam cross-sectional surface”.

As the light-emitting element 40, for example, a blue laser element that emits blue light, a green laser element that emits green light, a red laser element that emits red light, or the like can be employed. A light-emitting element that emits light other than these may also be employed.

Blue light refers to light having a light emission peak wavelength within the range from 420 nm to 494 nm. Green light refers to light having a light emission peak wavelength within the range from 495 nm to 570 nm. Red light refers to light having a light emission peak wavelength within the range from 605 nm to 750 nm.

Examples of the light-emitting element that emits blue light or the light-emitting element that emits green light include a semiconductor light-emitting element containing a nitride semiconductor. For example, GaN, InGaN, or AlGaN can be used as the nitride semiconductor. Examples of the light-emitting element that emits red light include one containing an InAlGaP-based, GaInP-based, GaAs-based, or AlGaAs-based semiconductor.

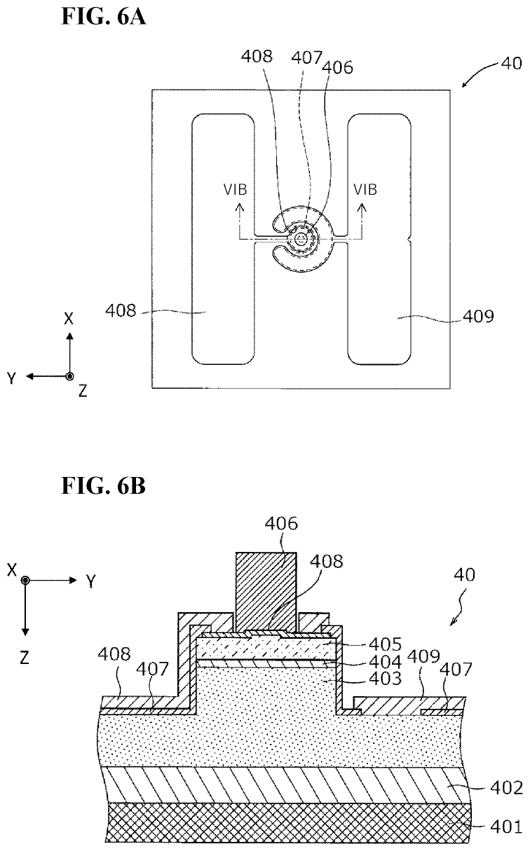

A configuration example of a VCSEL element used as the light-emitting element 40 is illustrated in FIGS. 6A and 6B. FIG. 6A is a schematic plan view for describing a structure of the light-emitting element 40 according to one embodiment, and FIG. 6B is a cross-sectional view taken along a section line VIB-VIB in FIG. 6A. The VCSEL element illustrated in FIGS. 6A and 6B has a layered structure in which a semiconductor substrate 401, an n-side reflective film 402, an n-type semiconductor layer 403, an active layer 404, a p-type semiconductor layer 405, and a p-side reflective film 406 are layered in this order in the −Z direction. The conductivity types of the p-type and the n-type may be reversed. The semiconductor substrate 401 may be removed. The n-type semiconductor layer 403 includes a flat plate portion and a protruding portion protruding therefrom in the −Z direction. The active layer 404 is provided on an upper surface of the protruding portion of the n-type semiconductor layer 403. The p-type semiconductor layer 405 is provided on an upper surface of the active layer 404, and the p-side reflective film 406 is provided in a region other than a peripheral region of an upper portion of the p-type semiconductor layer 405. A positive electrode 408 may be provided between the p-type semiconductor layer 405 and the p-side reflective film 406.

The VCSEL element includes an insulating layer 407 that covers an upper surface of the flat plate portion and a lateral surface of the protruding portion of the n-type semiconductor layer 403, a lateral surface of the active layer 404, and a lateral surface and a peripheral region of an upper surface of the p-type semiconductor layer 405. The VCSEL element includes the positive electrode 408 electrically connected to the p-type semiconductor layer 405 and a negative electrode 409 electrically connected to the n-type semiconductor layer 403. The uppermost surface of the VCSEL element disposed over the upper surface 20a of the base 20 is a surface opposite to a surface in contact with the n-side reflective film 402 of the semiconductor substrate 401.

The n-side reflective film 402 and the p-side reflective film 406 may each be formed of, for example, a distributed bragg reflector (DBR). The DBR has a structure in which a plurality of high refractive index layers and a plurality of low refractive index layers are alternately layered. The DBR includes a wavelength region of high reflectance called a stop band. A center wavelength and a wavelength width of the stop band are determined by a refractive index and a thickness of the high refractive index layer and a refractive index and a thickness of the low refractive index layer. The reflectance in the stop band of the DBR increases with the refractive index difference between the high refractive index layer and the low refractive index layer and with the number of layers.

In the example illustrated in FIG. 6B, a standing wave is formed between the n-side reflective film 402 and the p-side reflective film 406. A wavelength of the standing wave in the atmosphere is within the stop bands of the n-side reflective film 402 and the p-side reflective film 406, and this wavelength is an oscillation wavelength of the laser light. An integral multiple of a half of the oscillation wavelength is equal to an optical distance between reflective surfaces of the n-side reflective film 402 and the p-side reflective film 406 opposed to each other. The optical distance is a distance obtained by multiplying a distance in which light actually propagates through a certain medium by a refractive index of the medium. By applying a forward voltage between the positive electrode 408 and the negative electrode 409, current can be injected into the active layer 404. By the current injection, population inversion occurs in the active layer 404, and amplification of light by stimulated emission at the oscillation wavelength, that is, laser oscillation occurs. In the VCSEL element of the present embodiment, it is assumed that the side of the positive electrode 408 and the negative electrode 409 is a mounting surface and laser light is extracted from the side of the semiconductor substrate 401.

Note that the configuration of the VCSEL element illustrated in FIGS. 6A and 6B is an example. The components included in the VCSEL element may be formed using known materials. The shape of some of the components included in the VCSEL element may be changed, or other components may be further included. Laser light may be extracted from the side opposite to the semiconductor substrate 401.

The VCSEL element is superior to the edge-emitting laser element in that a more circular beam shape can be obtained, a two-dimensional array can be relatively easily obtained by two-dimensionally arranging a plurality of emitters, and the VCSEL element can be driven with low power consumption because the VCSEL element can be used in the range of several mW or less of optical output. Further, the VCSEL element is also excellent in that, since a beam having a narrow divergence angle can be emitted, even if an emitter pitch is reduced, the beam cross-sectional surfaces do not overlap with each other. The divergence angles of the blue and green VCSEL elements are preferably 10° or less at FWHM, and more preferably 8° or less at FWHM, for example, in the FFP.

Functional Element 50

In the present embodiment, examples of the functional element 50 include a light-receiving element, a temperature sensor, a protection element, a transistor, and a capacitor. The light-receiving element is, for example, a photodiode, and is an element for measuring the intensity of at least a part of the light emitted from the light-emitting element 40. The temperature sensor is, for example, a thermistor, and is an element for measuring temperature. The protection element is, for example, a Zener diode, and is an element for protecting the light-emitting element 40 by maintaining a voltage applied to the light-emitting element 40 at a certain level or less.

Wire 70

The wire 70 is used as an electrical bonding member. The wire 70 is a metal wire, and as the metal, for example, a metal, such as gold, silver, copper, platinum, or aluminum, or an alloy thereof can be used.

Lid Body 60

The lid body 60 in the present embodiment is a flat plate-shaped member including an upper surface 60a and a lower surface 60b. A thickness in the Z direction of the lid body 60 in the present embodiment is in the range from 0.1 mm to 2 mm, and may be, for example, about 0.4 mm. At least a portion of the lid body 60 through which a light L passes is formed of a light-transmissive material. Examples of the light-transmissive material include materials such as glass, sapphire, glass containing a phosphor, and transparent ceramic. A portion of the lid body 60 through which the light L does not pass may be formed of, for example, silicon, glass, ceramic, or the same material as that of the substrate 10 or the frame body 30 described above. In the lid body 60, an antireflection film may be provided on the lower surface 60b on which the light L is incident and/or the upper surface 60a from which the light L is emitted of a portion through which the light L passes.

As illustrated in FIG. 1B, the lid body 60 may include a light-blocking film 80 at least around the portion through which the light L passes of the upper surface 60a and/or the lower surface 60b. The light-transmitting portion 82 may have a circular shape, an elliptical shape, a rectangular shape, or the like, and is not limited to these shapes. As the material of the light-blocking film, the same material as that of the first conductive member 16 can be used. In addition, by providing a metal film in a bonding region between the upper surface 30a of the frame body 30 and the lower surface 60b of the lid body 60, it is possible to improve bonding strength when bonding is performed via an inorganic bonding member, such as a solder material.

Subsequently, the light-emitting device 100 including the above-described components will be described using FIGS. 1A to 3.

Light-Emitting Device 100

As illustrated in FIGS. 2 and 3, the light-emitting device 100 includes the substrate 10, the base 20 disposed on the substrate 10, the light-emitting elements 40 disposed over the base 20, the frame body 30 connected to the substrate 10, and the functional elements 50 disposed on the substrate 10.

Dimensions of an outer shape of the light-emitting device 100, particularly the dimensions in the X direction and the Y direction, are appropriately set in accordance with the number and size of the light-emitting elements 40 to be mounted, the purpose of use of the light-emitting device 100, and the like. For example, the dimension in the X direction of the light-emitting device 100 illustrated in FIGS. 1A to 3 is 4 mm, the dimension in the Y direction is 3.6 mm, and the dimension in the Z direction is 1.4 mm. Needless to say, these dimensions are one example, and may be changed within a range that does not deviate from the spirit of the present invention.

The light-emitting element 40 is placed on the second conductive member 18 provided on the upper surface 20a of the base 20. An example in which the light-emitting element 40 (VCSEL element) illustrated in FIGS. 6A and 6B is mounted over the submount 22 illustrated in FIGS. 5A and 5B will be described.

The light-emitting element 40 is bonded to the submount 22 in a state in which the positive electrode 408 and the negative electrode 409 are opposed to the second conductive member 18. The bonding may be performed via the bonding layers 18d containing, for example, Au, Ag, or AuSn. The bonding layer 18d may be a bump or may be a paste.

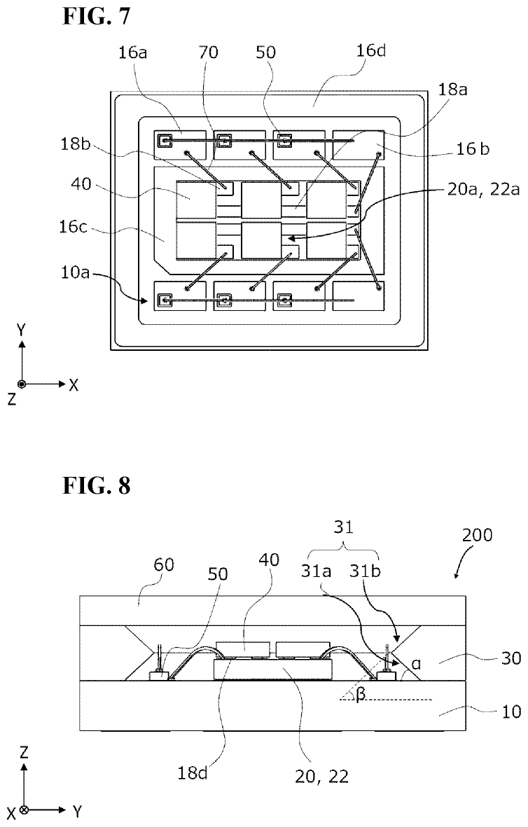

As illustrated in FIGS. 2 and 7, six light-emitting elements 40 are arranged in a two-dimensional array, two in the Y direction and three in the X direction, over the upper surface 22a of the submount 22 serving as the base 20. Note that frames surrounded by a broken line in the submount 22 illustrated in FIG. 5A are placement regions of the light-emitting elements 40. The common wiring line 18a is connected to electrodes of at least two light-emitting elements 40 among the plurality of light-emitting elements 40. In the example of FIG. 7, the negative electrodes 409 of three light-emitting elements 40 are connected to one common wiring line 18a. Each of the individual wiring lines 18b is connected to the positive electrode 408 of only one light-emitting element 40 among the plurality of light-emitting elements 40. These polarities may be reversed, and they are electrically connected as appropriate.

The connection wiring line 18c disposed on the lower surface 22c of the submount 22 and the heat dissipation wiring line 16c disposed on the upper surface 10a of the substrate 10 are connected to each other via, for example, a bonding layer. Examples of the bonding layer include a metal and an alloy, such as solder.

The common wiring line 18a disposed on the upper surface 22a of the submount 22 is connected to the cathode wiring line 16b disposed on the upper surface 10a of the substrate 10 by the wire 70. The individual wiring line 18b disposed on the upper surface 22a of the submount 22 is connected to the anode wiring line 16a disposed on the upper surface 10a of the substrate 10 by the wire 70. Thus, each of the light-emitting elements 40 is connected such that it can be independently driven. Since the common wiring lines 18a are arranged so as to be adjacent in two rows, the light-emitting elements 40 mounted on one common wiring line 18a are arranged so as to be rotated by 180° on an XY plane with respect to the light-emitting elements 40 arranged on the other common wiring line 18a. That is, two light-emitting elements 40 adjacent in the Y direction are disposed such that electrodes having the same polarity face each other.

In the present embodiment, the light-emitting element 40 is a single emitter, and an emitter pitch between adjacent light-emitting elements 40 may be in the range from 0.05 mm to 2 mm. In the present specification, the emitter pitch refers to a distance between the centers of the beam cross-sectional surfaces. For example, in the light-emitting device 100 illustrated in FIGS. 1A to 3, the emitter pitch in the X direction is 0.8 mm, and the emitter pitch in the Y direction is 0.55 mm. The emitter pitch in the X direction and the emitter pitch in the Y direction may be the same or may be different.

Note that the number of emitters and the emitter pitch can be appropriately increased or decreased according to the purpose of the light-emitting device. By using the multi-emitter described above, it is possible to further narrow the emitter pitch.

The plurality of light-emitting elements 40 may have the same emission color or different emission colors. For example, red, blue, and green VCSEL elements may be used. Thus, the light-emitting device can be suitable for a head-mounted display.

The functional element 50 is disposed on the upper surface 10a of the substrate 10. FIG. 7 is a view of the light-emitting device 100 in a state in which the frame body 30 and the lid body 60 are removed. In the present embodiment, the functional element 50 is a Zener diode including positive and negative electrodes on an upper surface and a lower surface of the functional element 50. The functional element 50 is bonded to the first conductive member 16 via a conductive bonding material containing Au, Ag, AuSn, or the like.

In the present embodiment, since the functional element 50 is the Zener diode, the light-emitting element 40 and the functional element 50 are electrically connected in parallel by connecting the first conductive member 16 and the second conductive member 18 by the wire 70. In the present embodiment, electrodes on upper surfaces of adjacent functional elements 50 are connected to each other by the wire 70.

The inner wall surface 31 of the frame body 30 surrounds the base 20 and the light-emitting element 40. The inner wall surface 31 includes the inclined surface 31a that is inclined increasing a distance from the light-emitting element 40 from the upper surface 30a toward the lower surface 30b. In other words, the inclined surface 31a is inclined such that an inclination angle α described later is an acute angle. The lower surface 30b of the frame body 30 is connected to the upper surface 10a of the substrate 10. The connection wiring line 16d disposed on the upper surface 10a of the substrate 10 can be connected to the lower surface 30b of the frame body 30 via, for example, a bonding layer. Examples of the material of the bonding layer include a metal, such as copper and gold, and an alloy, such as solder.

As illustrated in FIG. 3, since the light-emitting elements 40 are disposed over the upper surface 20a of the base 20 and the functional elements 50 are disposed on the upper surface 10a of the substrate 10, the functional elements 50 are disposed below the light-emitting elements 40. The functional element 50 is disposed between the lateral surface 20b of the base 20 and the inclined surface 31a of the frame body 30. By making an area of the lower surface 30b of the frame body 30 serving as a bonding surface with the substrate 10 smaller than an area of the upper surface 30a of the frame body 30, it is possible to secure a larger space serving as a placement surface of the functional element 50.

In addition, instead of the functional element 50 or together with the functional element 50, the wire 70 can be disposed in the above-described space. That is, as illustrated in FIG. 3, the wire 70 is wire-bonded to the first conductive member 16 provided on the upper surface 10a of the substrate 10, and at least a part of the wire 70 is disposed below the light-emitting elements 40. The wire 70 is disposed between the inclined surface 31a and the lateral surface 20b of the base 20. Thus, it is possible to secure a larger space for a bonding area when the wire 70 is wire-bonded, and make the light-emitting device more compact.

In the example illustrated in FIG. 3, at least a part of the functional element 50 and/or the wire 70 overlaps with the frame body 30 in a top view. Since the functional element 50 and/or the wire 70 are disposed within the space generated by the inclination of the inclined surface 31a, the light-emitting device 100 can be more compact as compared with the case in which the functional element 50 and/or the wire 70 are disposed without providing such a space.

An inclination angle of the inclined surface 31a will be described with reference to FIG. 3. The inclination angle in the present embodiment is represented by an angle α formed by the inclined surface 31a and the upper surface 10a of the substrate 10. In other words, the inclined surface 31a is inclined at the inclination angle α with respect to the upper surface 10a of the substrate 10. The inclination angle α may be, for example, in the range from 35° to 70°, for example, in the range from 50° to 70°.

For example, in a case in which the material of the frame body 30 is silicon, the inclined surface can be formed by performing wet etching. For example, when wet etching is performed on a single-crystal silicon wafer having an orientation flat (110) in a surface orientation (100), a (111) surface is precipitated, and it is possible to collectively form inclined surfaces having the inclination angle α of 54.7°. With the sandblast processing, it is possible to collectively form inclined surfaces having the inclination angle α, for example, in the range of 50° to 80°.

The frame body 30 need to include at least the inclined surface 31a that is inclined increasing a distance from the light-emitting element 40 from the upper surface 30a toward the lower surface 30b, but may have other surfaces. For example, FIG. 8 illustrates another light-emitting device 200 according to the present embodiment, and as illustrated in this FIG. 8, the inner wall surface 31 of the frame body may include an inclined surface 31b (example of an additional inclined surface) inclined so as to approach the light-emitting element 40 from the upper surface 30a toward the lower surface 30b above the inclined surface 31a. In this example, the inclined surface 31b is inclined at an inclination angle β with respect to the upper surface 10a of the substrate 10. The inclination angle β may be, for example, in the range from 35° to 90°, and may be, for example, in the range from 70° to 90°. The inclination angle α and the inclination angle β may be the same or may be different.

The inclined surface 31a and/or the inclined surface 31b may be provided with an insulating film. Since the light-emitting device 100 of the present embodiment is made compact, distances between the frame body 30 and components such as the submount 22, the functional element 50, and the wire 70, are extremely close. Therefore, in a case in which the frame body 30 is a conductive member, there is a concern that a failure, such as a short circuit, may occur due to the functional element 50 or the wire 70 coming into contact with the inclined surfaces 31a and 31b. These failures can be avoided by providing an insulating film on the inclined surface 31a and/or the inclined surface 31b. For example, SiO₂, SiN, or SiON can be used for the insulating film. Also, resin coating or ceramic coating may be performed.

As described above, the present invention having the technical features disclosed in the specification is not necessarily limited to the structure described in the embodiments of the specification. For example, the present invention may be applied to a light-emitting device including components not disclosed in the embodiment.

The light-emitting devices according to the embodiment can be utilized as light-emitting devices used for, for example, a head-mounted display, a biosensor, and optogenetics.

Throughout the contents described in the present specification, the following aspects of the technical matters are disclosed.

Aspect 1

A light-emitting device comprising: a substrate; a base disposed on the substrate; a light-emitting element disposed over the base; a frame body including an inner wall surface surrounding the base and the light-emitting element, an upper surface, and a lower surface, the lower surface being connected to the substrate; and at least one of a functional element and a wire disposed on the substrate, at least a part of the at least one of the functional element and the wire being disposed below the light-emitting element, wherein the inner wall surface includes an inclined surface that is inclined increasing a distance from the light-emitting element from the upper surface toward the lower surface, and the at least one of the functional element and the wire is disposed between the inclined surface and the base.

Aspect 2

The light-emitting device according to aspect 1, comprising a first conductive member on an upper surface of the substrate, wherein the functional element is disposed on the first conductive member.

Aspect 3

The light-emitting device according to aspect 1 or 2, comprising a second conductive member on an upper surface of the base, wherein the light-emitting element is placed on the second conductive member.

Aspect 4

The light-emitting device according to aspect 3 citing aspect 2, wherein the first conductive member and the second conductive member are connected by the wire.

Aspect 5

The light-emitting device according to any one of aspects 1 to 4, wherein the light-emitting element is a vertical cavity surface emitting laser.

Aspect 6

The light-emitting device according to any one of aspects 1 to 5, wherein at least a part of at least one of the functional element and the wire overlaps with the frame body in a top view.

Aspect 7

The light-emitting device according to any one of aspects 1 to 6, comprising an insulating film on a surface of the inclined surface.

Aspect 8

The light-emitting device according to any one of aspects 1 to 7, comprising a plurality of the light-emitting elements, wherein the plurality of light-emitting elements are arranged in a two-dimensional array.

Aspect 9

The light-emitting device according to aspect 8, comprising a second conductive member on an upper surface of the base, wherein the light-emitting element is placed on the second conductive member, and the second conductive member includes a common wiring line connected to electrodes of at least two light-emitting elements among the plurality of light-emitting elements, and an individual wiring line connected to an electrode of only one light-emitting element among the plurality of light-emitting elements.

Aspect 10

The light-emitting device according to aspect 9, comprising two or more of the common wiring lines, wherein the two or more common wiring lines are arranged in parallel.

Aspect 11

The light-emitting device according to any one of aspects 8 to 10, wherein the plurality of light-emitting elements are vertical cavity surface emitting lasers including a blue laser element that emits blue laser light, a green laser element that emits green laser light, and a red laser element that emits red laser light.

Aspect 12

The light-emitting device according to any one of aspects 1 to 11, comprising a lid body on an upper surface of the frame body.

Aspect 13

The light-emitting device according to aspect 12, wherein the lid body include a light-blocking film.

What is claimed is:

1. A light-emitting device comprising:
a substrate;
a base disposed on the substrate;
a light-emitting element disposed over the base;
a frame body including an inner wall surface surrounding the base and the light-emitting element, an upper surface, and a lower surface, the lower surface being connected to the substrate; and
at least one of a functional element and a wire disposed on the substrate, at least a part of the at least one of the functional element and the wire being disposed below the light-emitting element, wherein
the inner wall surface includes an inclined surface that is inclined so that a distance between the inclined surface and the light-emitting element increases from an upper surface side toward a lower surface side, and
the at least one of the functional element and the wire is disposed between the inclined surface and the base.

2. The light-emitting device according to claim 1, further comprising
a first conductive member on an upper surface of the substrate, wherein
the functional element is disposed on the first conductive member.

3. The light-emitting device according to claim 2, further comprising
a second conductive member on an upper surface of the base, wherein
the light-emitting element is disposed on the second conductive member.

4. The light-emitting device according to claim 3, wherein
the first conductive member and the second conductive member are connected by the wire.

5. The light-emitting device according to claim 1, wherein
the light-emitting element is a vertical cavity surface emitting laser.

6. The light-emitting device according to claim 1, wherein
at least a part of the at least one of the functional element and the wire overlaps with the frame body in a top view.

7. The light-emitting device according to claim 1, further comprising
an insulating film on a surface of the inclined surface.

8. The light-emitting device according to claim 1, further comprising
a plurality of additional light-emitting elements, wherein the light-emitting element and the additional light-emitting elements are arranged in a two-dimensional array.

9. The light-emitting device according to claim 8, further comprising
a second conductive member on an upper surface of the base, wherein
the light-emitting element is disposed on the second conductive member, and
the second conductive member includes
a common wiring line connected to electrodes of at least two light-emitting elements among the light-emitting element and the additional light-emitting elements, and
an individual wiring line connected to an electrode of only one light-emitting element among the light-emitting elements and the additional light-emitting elements.

10. The light-emitting device according to claim 9, wherein
the second conductive member further includes one or more additional common wiring lines, and
the common wiring line and the additional common wiring lines are arranged in parallel.

11. The light-emitting device according to claim 8, wherein
the light-emitting element and the additional light-emitting elements are vertical cavity surface emitting lasers including a blue laser element configured to emit blue laser light, a green laser element configured to emit green laser light, and a red laser element configured to emit red laser light.

12. The light-emitting device according to claim 1, further comprising
a lid body on an upper surface of the frame body.

13. The light-emitting device according to claim 12, wherein
the lid body include a light-blocking film.

14. The light-emitting device according to claim 1, wherein
the inner wall surface includes an additional inclined surface that is inclined so that a distance between the additional inclined surface and the light-emitting element increases from the lower surface side toward the upper surface side.

15. The light-emitting device according to claim 14, wherein
the additional inclined surface is connected to and disposed above the inclined surface.
